(19) United States
(12) Patent Application Publication
(10) Pub. No.: US 2002/0197875 A1
(43) Pub. Date: Dec. 26, 2002

(54) Method for controlling profile formation of low taper angle in metal thin film electorde

(75) Inventors: Wen-Jian Lin, Hsin-Chu (TW); Hung-Heui Hsu, Hsinchu (TW)

Correspondence Address: Daniel R. McClure, THOMAS, KAYDEN, HORSTEMEYER & RISLEY, L.L.P., Suite 1750, 100 Galleria Parkway, Atlanta, GA, 30339-5948, US

(73) Assignee: Prime View International Co., Ltd., Hsin-Chu (TW)

(21) Appl. No.: 09/886,361

(22) Filed: Jun. 21, 2001

(51) Int. Cl. H01L 21/311

(52) U.S. Cl. 438/701

(57) ABSTRACT

Disclosed is a method for controlling profile formation of low taper angle in metal thin film electrode applicable to manufacture of thin film transistor liquid crystal display in order for insulator capably deposited on the metal thin film electrode with good step coverage, by which a double-layer structure for metal electrode is formed with two metals on a substrate and then etched with a wet etching solution having a higher etching rate to the upper layer metal than that to the lower layer metal of the double-layer structure. By employing different etching rate and thickness to the double-layer metals, a metal electrode is formed with a very low taper angle and thus can be deposited with insulator of good step coverage thereon.

### FIELD OF THE INVENTION

The present invention relates generally to the manufacture of a thin film transistor liquid crystal display (TFT-LCD), and more particularly, to a method for controlling profile formation of low taper angle in metal thin film electrode within a TFT-LCD.

### BACKGROUND OF THE INVENTION

Liquid crystal displays (LCDs) are employed on notebook computers, personal digital assistants (PDAs), and color televisions due to their small size, low weight, low driving voltage, and low power consumption, and keep in the trend to replace conventional cathode ray tube (CRT) displays. An active matrix LCD device typically comprises a thin film transistor (TFT) array formed on a panel for pixel switching elements to influence the optical characteristics of pixel liquid crystal by controlling the thin film transistors so as to display images.

The manufacture process of a TFT comprises deposition and etching of various layers of material on a transparent substrate so as to form the structure of a transistor. FIG. 1 shows partial structure of a TFT, in which a metal film gate electrode 12 is formed on a transparent substrate 10 and covered with a gate insulator 16. In the structure of the TFT device, the profile of the metal film gate electrode 12 is crucial to the performance of step coverage while the gate insulator 16 is deposited on it. Therefore, the requirement of taper profile is necessary for the metal film gate electrode 12 in order to obtain a good step coverage of the gate insulator 16. In the fabrication of the TFT, wet etching process can hardly control the taper angle θ of the metal film gate electrode 12, while dry etching process, especially reactive ion etching (RIE) process, can easily control the taper angle θ. Usually, the taper angle θ of the metal film gate electrode 12 can be controlled in a range of about between 45 and 60 degrees by metal dry etching process due to the original profile of photo resist thereon. However, wet etching process is better than dry etching process when concerning on the production throughput, running cost, and the etching selectivity for under layer. It is thus an important issue to obtain a good taper profile of metal film gate electrode by wet etching process.

In the prior art, methods of making a metal film electrode with a good taper angle thereof by wet etching process are never proposed. Therefore, it is desirable a method for controlling profile formation of low taper angle in metal thin film electrode by wet etching process in order for insulator capably deposited on the metal thin film electrode with a good step coverage.

### SUMMARY OF THE INVENTION

The present invention is directed to a method of forming metal thin film electrode with low taper angle profile by wet etching process, so as to lower the manufacture cost and increase the product on throughput. While it is further advantageous for insulator with a good step coverage being deposited on the metal thin film electrode, resulted in an increase of yield in the manufacture of a TFT-LCD.

According to the present invention, a method for controlling profile formation of low taper angle in metal thin film electrode comprises depositing a double-layer structure formed of two metals for an electrode on a transparent substrate with the upper layer metal thinner than that of the lower layer metal, and wet etching the double-layer structure with a solution having a higher etching rate to the upper layer metal than that to the lower layer metal. The upper layer metal is so thin and etched faster than the lower layer metal that a very low taper angle profile is formed with the resultant metal electrode. As a result, the insulator subsequently deposited on the metal electrode receives a good step coverage.

It is easy to make a taper angle smaller than 10 degrees in accordance with the present invention, which is even better than traditional dry etching process. In a preferred embodiment, a metal electrode with a taper angle of 7.5 degrees is implemented.

Wet etching process is employed to make the metal electrode in accordance with the present invention, so that the yield and production throughput in the fabrication of a TFT array are both increased and the manufacture cost is cut down, due to the high production throughput, low running cost, flexible etching selectivity to under layer for the wet etching process, the low taper angle profile of the metal electrode thus formed, and the good step coverage for the insulator subsequently deposited on the metal electrode.

### BRIEF DESCRIPTION OF THE DRAWINGS

For a better understanding of the present invention, reference may be had to the following description of exemplary embodiment thereof, considered in conjunction with the accompanying drawings, in which:

FIG. 1 illustrates a structure of gate electrode for a thin film transistor;

FIG. 2 illustrates a structure in one embodiment of the present invention; and

FIG. 3 illustrates one embodiment process to make the structure shown in FIG. 2, in which FIG. 3(A) shows the structure of a double-layer metal deposited on a substrate, FIG. 3(B) is a patterning step to define the gate electrode, and FIG. 3(C) shows the gate electrode when it is completed.

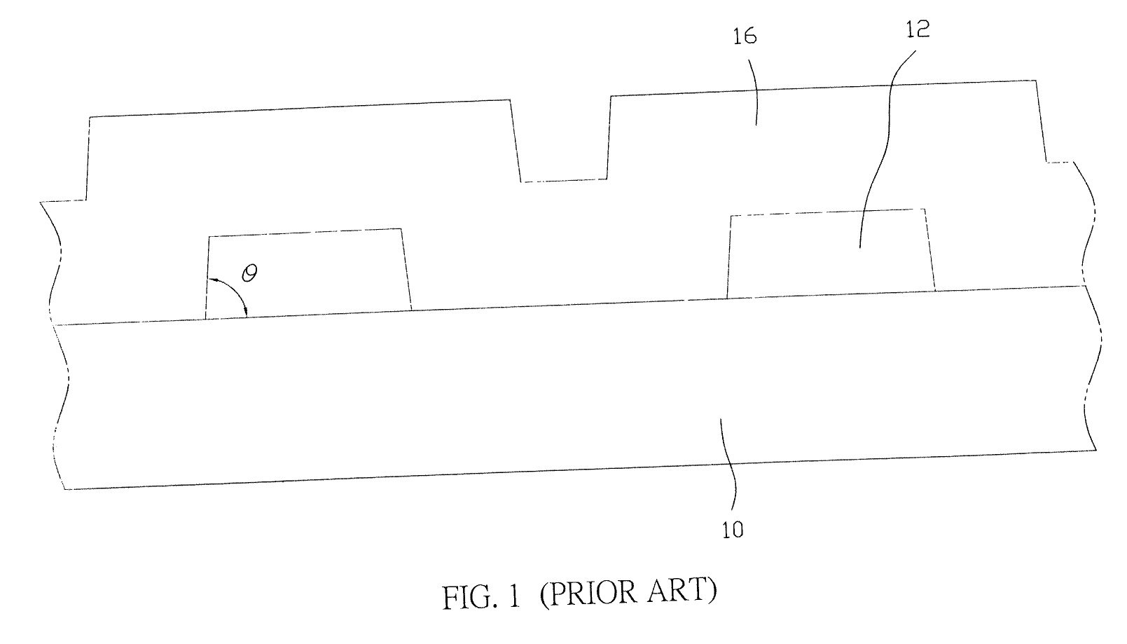

### DETAILED DESCRIPTION OF THE INVENTION

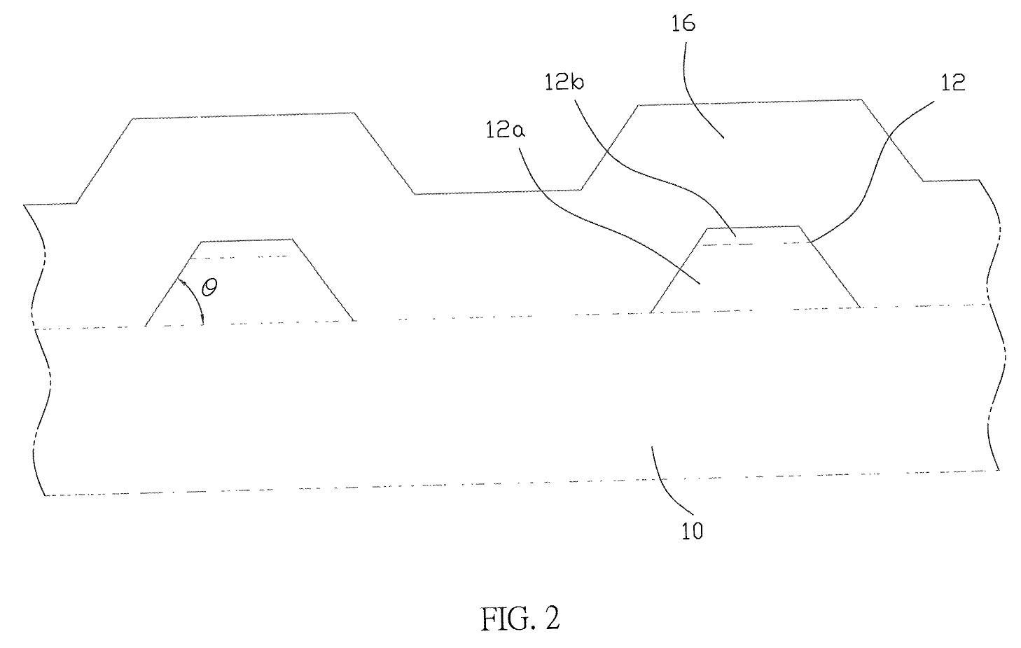

FIG. 2 illustrates one embodiment of the present invention, in which a double-layer structure of two metals with a lower layer metal 12a and an upper layer 12b is formed on a transparent substrate 10 for a gate electrode 12 and is deposited with a gate insulator 16 thereon. The upper layer 12b is thinner than that of the lower layer 12a and has a higher etching rate than that to the lower layer metal 12a to a wet etching solution. In a preferred embodiment, a Mo/Cr alloy in a thickness of around 200 nm is used for the lower layer metal 12a, and an Al-base material in a thickness of around 50 nm is used for the upper layered metal 12b, wherein a taper angle θ of about 7.5 degrees is reached.

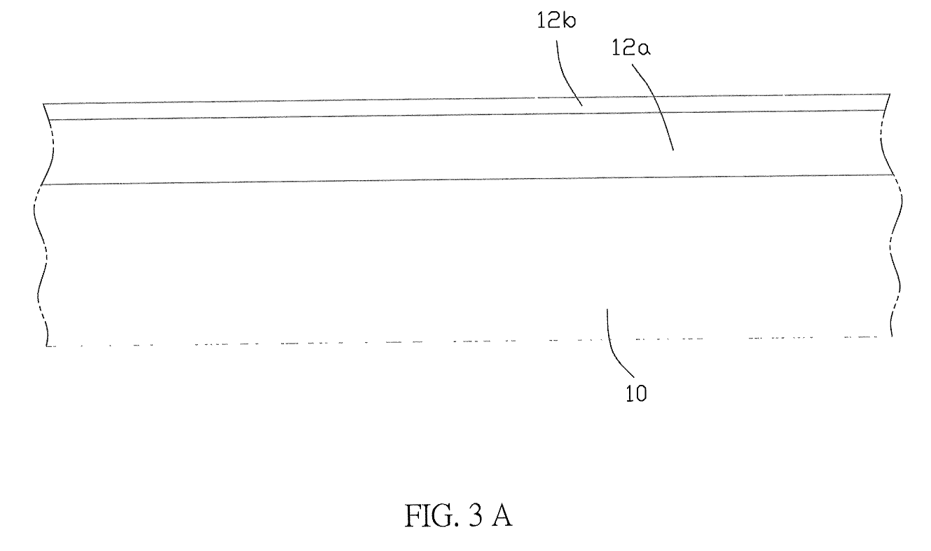

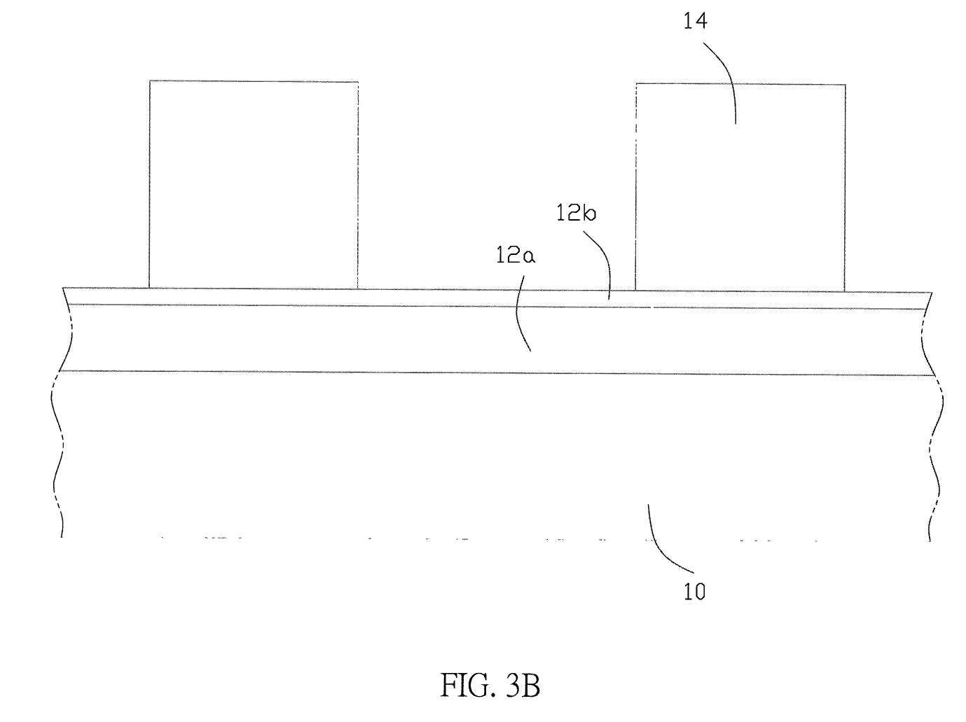

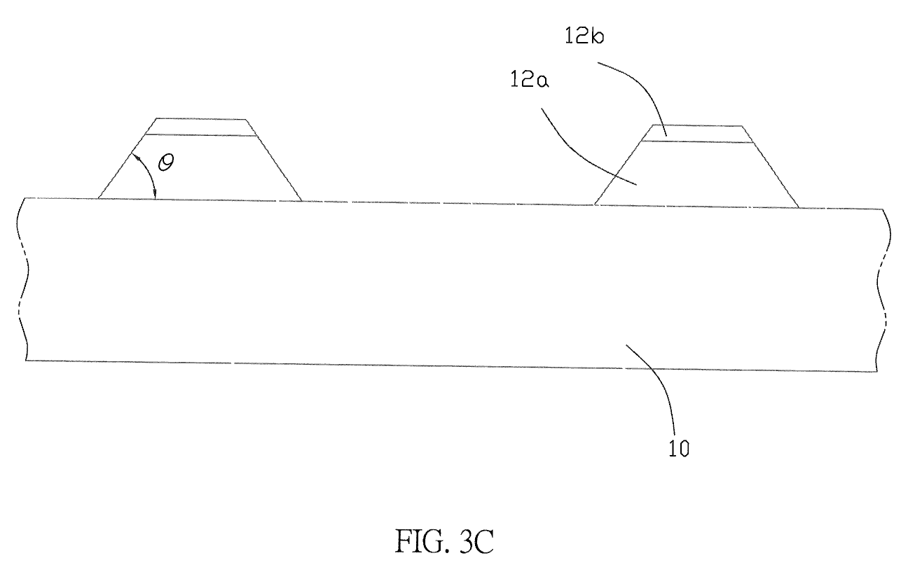

One embodiment process to implement the structure shown in FIG. 2 is illustrated in FIG. 3. As shown in FIG. 3(A), the transparent substrate 10 such as glass, quartz, plastic, and the like is provided to be deposited with the lower layer metal 12a and upper layer metal 12b in turn. The upper layer metal 12b is formed thinner than that of the lower layer metal 12a by a method such as sputtering with a material selected from chromium (Cr), aluminum (Al), copper (Cu), molybdenum (Mo), tantalum (Ta), titanium (Ti), and other low resistive metal or metallic alloy as the metal electrode. Typically, the thickness of the lower layer metal 12a is preferably formed in a range of about 100-500 nm, and the thickness of the upper layer metal 12b is preferably formed in a range of about 20-200 nm.

A photolithography process is subsequently applied for patterning the double-layer structure metals 12a and 12b, for example, by transferring the pattern of a mask onto a photo resist 14, as shown in FIG. 3(B). Then, a wet etching process is used to etch the metal layers 12a and 12b, by which the metal layers 12a and 12b are rapidly dipped in an etching solution. The etching solution is selected in accordance with the etching rate to the two metal layers 12a and 12b, typically in a range of between 2 and 5. After etched, the metal layers 12a and 12b are rinsed and cleaned, the photo resist 14 is removed, and the gate electrode 12 is thus formed, as shown in FIG. 3(C). An insulator is then deposited to form the structure shown in FIG. 2. Usually, an oxide, nitride, or other similar oxide material can be used for the insulator 16 by a method such as chemical vapor deposition (CVD) or plasma-enhanced chemical vapor deposition (PECVD). In general, silicon nitride and silicon dioxide can be formed in a reaction chamber respectively with SiH₄/NH₃/N₂/N₂O and SiH₂Cl₂/NH₃/N₂ or N₂O. The subsequent processes to form the other structure of the transistor can be the same as in the prior art, so no further description is needed.

For the etching rate of the solution in the wet etching process to the upper layer metal 12b is greater than that to the lower layer metal 12a and the upper layer metal 12b is very thin, a very low taper angle θ is formed with the gate electrode 12, which can be easily below 10 degrees, even better than conventional dry etching process. In a preferred embodiment, a Mo/Cr alloy in a thickness of around 200 nm is used for the lower layer metal 12a, an Al-base material in a thickness of around 50 nm is used for the upper layered metal 12b, and the etching solution used comprises H₃PO₄, HNO₃, or CH₃COOH, a taper angle θ of about 7.5 degrees is reached. Due to the low taper angle profile of the gate electrode 12, the gate insulator 16 subsequently deposited thereon receives a very good step coverage.

The method described hereof has the advantages of wet etching process such as high production throughput, low running cost, and flexible etching selectivity of the under layer. As a result, not only can this method employ wet etching process to control the profile formation of low taper angle in the gate electrode so that a good step coverage is obtained for the insulator, the yield and production throughput of the thin film transistor are also increased and the manufacture cost is thus cut down.

From the above, it should be understood that the embodiment described, in regard to the drawings, is merely exemplary and that a person skilled in the art may make variations and modifications to the shown embodiment without departing from the spirit and scope of the present invention. All variations and modifications are intended to be included within the scope of the present invention as defined in the appended claims.

What is claimed is:

1. A method for controlling profile formation of low taper angle in metal thin film electrode, comprising the following steps of:
forming a first metal layer of a first thickness;
forming a second metal layer of a second thickness on said first metal layer; and
etching said first and second metal layers with a solution having an etching rate to said second metal layer greater than that to said first metal layer.

2. A method of claim 1, wherein said first thickness is greater than said second thickness.

3. A method of claim 1, wherein said solution has an etching selectivity in a range of between 2 and 5.

4. A method of claim 1, wherein said first metal layer comprises a Mo/Cr alloy and said second metal layer comprises an Al-base material.

5. A method of claim 4, wherein said first thickness is about 200 nm, and said second thickness is about 50 nm.

6. A method of claim 4, wherein said solution comprises H₃PO₄, HNO₃, or CH₃COOH.

7. A method of claim 1, further comprising depositing an insulator on said metal layers.

8. A metal thin film electrode with low taper angle, comprising:
a first metal layer of a first thickness;
a second metal layer of a second thickness formed on said first metal layer; and
a taper angle formed with said metal layers by wet etching.

9. A metal thin film electrode of claim 8, wherein said first thickness is greater than said second thickness.

10. A metal thin film electrode of claim 8, wherein said taper angle is less than 10 degrees.

11. A metal thin film electrode of claim 8, wherein said first metal layer comprises a Mo/Cr alloy and said second metal layer comprises an Al-base material.

12. A metal thin film electrode of claim 11 wherein said first thickness is about 200 nm, and said second thickness is about 50 nm.

13. A metal thin film electrode of claim 12, wherein said taper angle is about 7.5 degrees.
